(19) United States
(12) Patent Application Publication
(10) Pub. No.: US 2022/0367436 A1
(43) Pub. Date: Nov. 17, 2022

(54) Cross-type semiconductor capacitor array layout

(71) Applicant: REALTEK SEMICONDUCTOR CORPORATION, Hsinchu (TW)

(72) Inventor: SHIH-HSIUNG HUANG, Hsinchu (TW)

(21) Appl. No.: 17/676,858

(22) Filed: Feb. 22, 2022

(30) Foreign Application Priority Data
May 11, 2021 (TW) 110116899

(51) Int. Cl. H01L 27/01

(52) U.S. Cl. CPC H01L 27/01

(57) ABSTRACT

A cross-type semiconductor capacitor layout includes a first conductive structure and a second conductive structure. The first conductive structure includes longitudinal first conductive strips and lateral first conductive strips. The second conductive structure includes longitudinal second conductive strips and lateral second conductive strips. The longitudinal first conductive strips and the longitudinal second conductive strips are alternately disposed in a first integrated circuit layer. The lateral first conductive strips and the lateral second conductive strips are alternately disposed in a second integrated circuit layer. The lateral first conductive strips are coupled to the longitudinal first conductive strips through vias. The lateral second conductive strips are coupled to the longitudinal second conductive strips through vias. The cross-type semiconductor capacitor layout can mitigate the problem of parasitic capacitance and prevent the problem caused by a U-shaped structure applied in an advanced process.

### BACKGROUND OF THE INVENTION

### 1. Field of the Invention

The present disclosure relates to a semiconductor capacitor array layout, especially to a cross-type semiconductor capacitor array layout.

### 2. Description of Related Art

A general semiconductor integrated circuit (IC) is in the form of a multilayer structure. A conventional semiconductor capacitor array is usually located in a single metal layer of the multilayer structure. The semiconductor capacitor array usually includes multiple rows of capacitor units that are arranged in parallel and include a first row of capacitor units (hereafter referred to as “first capacitor row”) and a second row of capacitor units (hereafter referred to as “second capacitor row”). In order to avoid an upper electrode (lower electrode) of the first capacitor row and the trace of a lower electrode (upper electrode) of the second capacitor row jointly generating parasitic capacitance having influence on the accuracy of capacitance of the capacitor units, the gap between the first capacitor row and the second capacitor row needs to be broaden; however, this wastes circuit area. In regard to the above case, the upper electrode (lower electrode) of the first capacitor row is parallel to the trace of the lower electrode (upper electrode) of the second capacitor row and thereby contributes additional capacitance, and this affects the accuracy of capacitance of the capacitor units.

There are other problems with respect to a conventional semiconductor capacitor array. The design of a capacitor unit of some conventional semiconductor capacitor array is shown in Fig. 1a. In Fig. 1a, the upper electrode 110 is in the form of a U-shaped structure including two longitudinal parts and one lateral part, the lower electrode 120 is in the form of a strip-shaped structure. In comparison with a general mature process, in some advanced process (e.g., a Fin Field-Effect Transistor (FinFET) process) the ratio (W/L) of the width “W” of the lateral part of the U-shaped structure to the length “L” of the longitudinal part of the U-shaped structure should be larger as shown in Fig. 1b to conform to the specification of the advanced process. Since a semiconductor capacitor array usually includes a large amount of capacitor units, once the ratio (W/L) of the U-shaped structure of every capacitor unit is enlarged, the overall semiconductor capacitor array will consume a lot of additional circuit area. It should be noted that Figs. 1a-1b show the variation in the ratio (W/L) of the U-shaped structure rather than the actual size of the U-shaped structure.

### SUMMARY OF THE INVENTION

An object of the present disclosure is to provide a cross-type semiconductor capacitor array layout as an improvement over the prior art.

A first embodiment of the cross-type semiconductor capacitor array layout of the present disclosure includes a first conductive structure and a second conductive structure. The first conductive structure includes longitudinal first conductive strips and lateral first conductive strips. The second conductive structure includes longitudinal second conductive strips and lateral second conductive strips.

In regard to the first embodiment, the longitudinal first conductive strips are located in a first integrated circuit (IC) layer and include a first longitudinal first-conductive-strip group and a second longitudinal first-conductive-strip group. The first longitudinal first-conductive-strip group is located in a first layout region of the first IC layer. The second longitudinal first-conductive-strip group is located in a second layout region of the first IC layer. The first layout region is adjacent to the second layout region. Each of the first and second longitudinal first-conductive-strip groups includes M longitudinal first conductive strips, wherein the M is an integer greater than one. The M longitudinal first conductive strips jointly define (M−1) gap(s). The first longitudinal first-conductive-strip group and the second longitudinal first-conductive-strip group as a whole include 2M longitudinal first conductive strips. The lateral first conductive strips are located in a second IC layer and include N lateral first conductive strips, wherein the N is an integer greater than one. A first part of the N lateral first conductive strips is located in a first vertical projection region of the first layout region, and a second part of the N lateral first conductive strips is located in a second vertical projection region of the second layout region. Both the first vertical projection region and the second vertical projection region are in the second IC layer. The N lateral first conductive strips jointly define (N−1) gap(s). The N lateral first conductive strips are coupled to the 2M longitudinal first conductive strips through first vias.

In regard to the first embodiment, the longitudinal second conductive strips are located in the first IC layer and include a first longitudinal second-conductive-strip group and a second longitudinal second-conductive-strip group. Each of the first and second longitudinal second-conductive-strip groups includes (M−1) longitudinal second conductive strip(s). The (M−1) longitudinal second conductive strip(s) of the first longitudinal second-conductive-strip group is/are positioned in the (M−1) gap(s) defined by the first longitudinal first-conductive-strip group, and is/are electrically insulated from the first longitudinal first-conductive-strip group. The (M−1) longitudinal second conductive strip(s) of the second longitudinal second-conductive-strip group is/are positioned in the (M−1) gap(s) defined by the second longitudinal first-conductive-strip group, and is/are electrically insulated from the second longitudinal first-conductive-strip group. The lateral second conductive strips are located in the second IC layer and include a first lateral second-conductive-strip group and a second lateral second-conductive-strip group. Each of the first and second lateral second-conductive-strip groups includes (N−1) lateral second conductive strip(s), and is electrically insulated from the lateral first conductive strips. The (N−1) lateral second conductive strip(s) of the first lateral second-conductive-strip group is/are located in the first vertical projection region, positioned in the (N−1) gap(s) defined by the N lateral first conductive strips, and coupled to the (M−1) longitudinal second conductive strip(s) of the first longitudinal second-conductive-strip group through second vias. The (N−1) lateral second conductive strip(s) of the second lateral second-conductive-strip group is/are located in the second vertical projection region, positioned in the (N−1) gap(s) defined by the N lateral first conductive strips, and coupled to the (M−1) longitudinal second conductive strip(s) of the second longitudinal second-conductive-strip group through third vias.

A second embodiment of the cross-type semiconductor capacitor array layout of the present disclosure includes a first conductive structure and a second conductive structure. The first conductive structure includes longitudinal first conductive strips and lateral first conductive strips. The second conductive structure includes longitudinal second conductive strips and lateral second conductive strips. The longitudinal first conductive strips and the longitudinal second conductive strips are alternatively disposed in a first IC layer. The lateral first conductive strips and the lateral second conductive strips are alternatively disposed in a second IC layer. The lateral first conductive strips are coupled to the longitudinal first conductive strips through first vias. The lateral second conductive strips are coupled to the longitudinal second conductive strips through second vias.

These and other objectives of the present invention will no doubt become obvious to those of ordinary skill in the art after reading the following detailed description of the preferred embodiments that are illustrated in the various figures and drawings.

### BRIEF DESCRIPTION OF THE DRAWINGS

Fig. 1a shows the design of a capacitor unit according to the prior art.

Fig. 1b shows how the design of the capacitor unit in Fig. 1a is modified to conform to the specification of an advanced process.

FIG. 2 shows an embodiment of the cross-type semiconductor capacitor array layout of the present disclosure.

FIG. 3 shows another embodiment of the cross-type semiconductor capacitor array layout of the present disclosure.

### DETAILED DESCRIPTION OF THE PREFERRED EMBODIMENTS

The semiconductor capacitor array layout of the present disclosure can mitigate the problem of the prior art about parasitic capacitance and can prevent the problem caused by the U-shaped structure of the prior art applied in an advanced process.

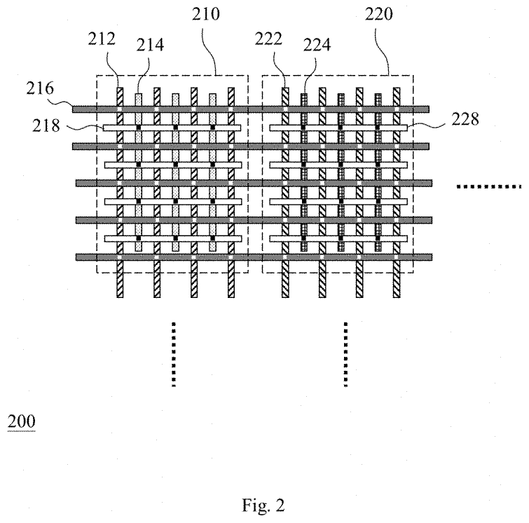

FIG. 2 shows an embodiment of the cross-type semiconductor capacitor array layout of the present disclosure. The cross-type semiconductor capacitor array layout 200 of FIG. 2 includes a first conductive structure and a second conductive structure. The first conductive structure includes longitudinal first conductive strips (i.e., the longitudinal strips 212 marked with slashes and the longitudinal strips 222 marked with backslashes in FIG. 2) and lateral first conductive strips (i.e., the gray lateral strips 216 in FIG. 2). The second conductive structure includes longitudinal second conductive strips (i.e., the longitudinal strips 214 marked with dots and the longitudinal strips 224 marked with grids in FIG. 2) and lateral second conductive strips (i.e., the white lateral strips 218 and 228 in FIG. 2).

In regard to the embodiment of FIG. 2, the cross-type semiconductor capacitor array layout 200 is included in an integrated circuit (IC) structure (not shown) which includes a substrate and multiple IC layers formed on/above the substrate. Normally, the first conductive structure functions as a top electrode and the second conductive structure functions as a bottom electrode; however, the first conductive structure and the second conductive structure may function as the bottom electrode and the top electrode respectively, if practicable. It should be noted that the longitudinal first/second conductive strips are parallel in a first direction (i.e., the longitudinal direction), and the lateral first/second conductive strips are parallel in a second direction (i.e., the lateral direction). The first direction is perpendicular to the second direction, but the implementation of the present invention is not limited thereto.

In regard to the embodiment of FIG. 2, the longitudinal first conductive strips are located in a first IC layer (e.g., a Z^{th} metal layer of the aforementioned multiple IC layers, wherein the Z is positive integer) and include a first longitudinal first-conductive-strip group (i.e., the group composed of the longitudinal strips 212 marked with slashes in FIG. 2) and a second longitudinal first-conductive-strip group (i.e., the group composed of longitudinal strips 222 marked with backslashes in FIG. 2). The first longitudinal first-conductive-strip group is located in a first layout region 210. The second longitudinal first-conductive-strip group is located in a second layout region 220. The first layout region 210 is adjacent to the second layout region 220, and thus neither conductive strip nor conductor, that is capable of independently functioning as a capacitor, exists between the two layout regions; however, this is not the limitation to the implementation of the present invention. Each of the first and second longitudinal first-conductive-strip groups includes M longitudinal first conductive strips, wherein the M is an integer greater than one (e.g., M=4 in FIG. 2). The M longitudinal first conductive strips jointly define (M−1) gap(s); accordingly, the first longitudinal first-conductive-strip group and the second longitudinal first-conductive-strip group as a whole include 2M longitudinal first conductive strips.

In regard to the embodiment of FIG. 2, The lateral first conductive strips are located in a second IC layer (e.g., the (Z+1)^{th} metal layer or the (Z−1)^{th} metal layer of the aforementioned multiple IC layers, wherein no metal layer is between the first IC layer and the second IC layer) and include N lateral first conductive strips (i.e., the gray lateral strips 216 in FIG. 2), wherein the N is an integer greater than one (e.g., N=5 in FIG. 2). A first part of the N lateral first conductive strips is located in a first vertical projection region of the first layout region 210 (e.g., the region right above the first layout region 210), and a second part of the N lateral first conductive strips is located in a second vertical projection region of the second layout region 220 (e.g., the region right above the second layout region 220). The N lateral first conductive strips jointly define (N−1) gap(s). The N lateral first conductive strips are coupled to the 2M longitudinal first conductive strips through first vias (i.e., the white blocks coupling the N lateral first conductive strips 216 to the 2M longitudinal first conductive strips 212 and 222 in FIG. 2). In this embodiment, the number of the first vias is not greater than (2M×N) and is not fewer than the smaller one among N and 2M; however, this is not the limitation to the implementation of the present invention when an alternative means is available. It should be noted that no lateral conductive strip is disposed in any of the first layout region 210 and the second layout region 220, and no longitudinal conductive strip is disposed in any of the first vertical projection region and the second vertical projection region; however, this is not the limitation to the implementation of the present invention.

In regard to the embodiment of FIG. 2, the longitudinal second conductive strips are located in the first IC layer and include a first longitudinal second-conductive-strip group (i.e., the group composed of the longitudinal strips 214 marked with dots in FIG. 2) and a second longitudinal second-conductive-strip group (i.e., the group composed of the longitudinal strips 224 marked with grids in FIG. 2). Each of the first and second longitudinal second-conductive-strip groups includes (M−1) longitudinal second conductive strip(s). The (M−1) longitudinal second conductive strip(s) of the first longitudinal second-conductive-strip group is/are respectively positioned in the (M−1) gap(s) defined by the first longitudinal first-conductive-strip group (i.e., the group composed of the longitudinal strips 212 in FIG. 2), and is/are electrically insulated from the first longitudinal first-conductive-strip group. The (M−1) longitudinal second conductive strip(s) of the second longitudinal second-conductive-strip group is/are respectively positioned in the (M−1) gap(s) defined by the second longitudinal first-conductive-strip group (i.e., the group composed of the longitudinal strips 222 in FIG. 2), and is/are electrically insulated from the second longitudinal first-conductive-strip group. In this embodiment, the electrical insulation between two conductive strips can be realized with a known/self-developed means such as oxide formed between the two conductive strips.

In regard to the embodiment of FIG. 2, the lateral second conductive strips are located in the second IC layer and include a first lateral second-conductive-strip group (i.e., the white lateral strips 218 in FIG. 2) and a second lateral second-conductive-strip group (i.e., the white lateral strips 228 in FIG. 2). Each of the first and second lateral second-conductive-strip groups includes (N−1) lateral second conductive strip(s), and is electrically insulated from the lateral first conductive strips (i.e., the gray lateral strips 216 in FIG. 2). The (N−1) lateral second conductive strip(s) of the first lateral second-conductive-strip group is/are located in the aforementioned first vertical projection region (i.e., the region right above/below the first layout region 210), respectively positioned in the (N−1) gap(s) defined by the N lateral first conductive strips (i.e., the gray lateral strips 216 in FIG. 2), and coupled to the (M−1) longitudinal second conductive strip(s) of the first longitudinal second-conductive-strip group through second vias (i.e., the black blocks coupling the (N−1) lateral second conductive strip(s) 218 with the (M−1) longitudinal second conductive strip(s) 214 in FIG. 2). The (N−1) lateral second conductive strip(s) of the second lateral second-conductive-strip group is/are located in the aforementioned second vertical projection region (i.e., the region right above/below the second layout region 220), positioned in the (N−1) gap(s) defined by the N lateral first conductive strips (i.e., the gray lateral strips 216 in FIG. 2), and coupled to the (M−1) longitudinal second conductive strip(s) of the second longitudinal second-conductive-strip group through third vias (i.e., the black blocks coupling the (N−1) lateral second conductive strip(s) 228 with the (M−1) longitudinal second conductive strip(s) 224 in FIG. 2). In this embodiment, each of the number of the second vias and the number of the third vias is not greater than [(M−1)×(N−1)] and is not fewer than the smaller one among (N−1) and (M−1); however, this is not the limitation to the implementation of the present invention when an alternative means is available. It should be noted that the length of any of the aforementioned N lateral first conductive strips (i.e., the gray lateral strips 216 in FIG. 2) is longer than the length of any of the (N−1) lateral second conductive strips (i.e., the white lateral strips 218 and 228 in FIG. 2), but the implementation of the present invention is not limited thereto.

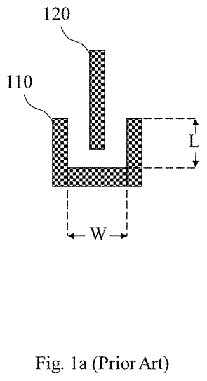

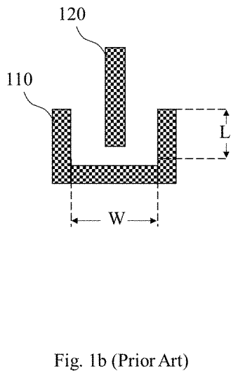

In regard to the embodiment of FIG. 2, in the first layout region 210 and the first vertical projection region above/below the first layout region 210, the first conductive structure and the second conductive structure jointly form a first capacitor unit; and in the second layout region 220 and the second vertical projection region above/below the second layout region 220, the first conductive structure and the second conductive structure jointly form a second capacitor unit. Each of the first and second capacitor units can be the minimum capacitor unit of the cross-type semiconductor capacitor array layout 200, but the implementation of the present invention is not limited thereto. In light of the above, since all the conductive strips in the first/second layout region 210/220 are longitudinal strips and all the conductive strips in the first/second vertical projection region are lateral strips, the capacitor units in the these regions are not in the form of U-shaped structures and can be manufactured without wasting circuit area and be manufactured in compliance with the specification of an advanced process (e.g., a Fin Field-Effect Transistor (FinFET) process). For example, the specification of a FinFET process requires that a ratio of the width to the length (W/L) of a U-shaped structure (e.g., the U-shaped structure in Fig. 1b) should be larger in comparison with the W/L of a U-shaped structure (e.g., the U-shaped structure in Fig. 1a) under the specification of a conventional process, and since the capacitor units of the cross-type semiconductor capacitor array layout 200 are not in the form of U-shaped structures, these capacitor units can be manufactured without the limitation of the U-shaped structures and be cost-effective in circuit area.

It should be noted that the semiconductor capacitor array layout 200 of FIG. 2 may include other capacitor units as illustrated with the ellipses in FIG. 2 which are used for the prevention of a complicated drawing. Each of the other capacitor units can be the aforementioned minimum capacitor unit or the modification thereof.

In regard to the embodiment of FIG. 2, the cross-type semiconductor capacitor array layout 200 may further include at least one first reference voltage supply strip (not shown) and K second reference voltage supply strip(s) (not shown). The at least one first reference voltage supply strip is located in the aforementioned second IC layer (e.g., the (Z+1)^{th} metal layer or the (Z-1)^{th} metal layer) or located in a third IC layer (e.g., a metal layer different from the second IC layer), and is used for the transmission of a first reference voltage and coupled to the lateral first conductive strips (i.e., the gray lateral strips 216 in FIG. 2). When the at least one first reference voltage supply strip is not located in the second IC layer, the at least one first reference voltage supply strip (e.g., one longitudinal power supply strip) can be coupled to the N lateral first conductive strips through vias (e.g., N vias). The K second reference voltage supply strip(s) is/are located in the first/second/third IC layer or located in a fourth IC layer (e.g., a metal layer different from any of the first, second, and third IC layers), and is/are used for the transmission of a second reference voltage and coupled to the longitudinal second conductive stirps (i.e., the longitudinal strips 214 and 224 in FIG. 2) or the lateral second conductive strips (i.e., the lateral strips 218 and 228 in FIG. 2). The K second reference voltage supply strip(s) include(s) a first-capacitor-group power supply strip that is coupled to at least one of the aforementioned first lateral second-conductive-strip group and the aforementioned second lateral second-conductive-strip group or coupled to at least one of the aforementioned first longitudinal second-conductive-strip group and the aforementioned second longitudinal second-conductive-strip group; accordingly, the first-capacitor-group power supply strip is coupled to at least one of the aforementioned first and second capacitor units. In brief, all the capacitor units coupled to the first-capacitor-group power supply strip belong to the same capacitor group which can be treated as a larger capacitor. It should be noted that the above-mentioned electrical coupling may be realized through vias or the like, and this is common in this technical field; furthermore, the number of vias for electrical coupling can be determined according to the demand for implementation.

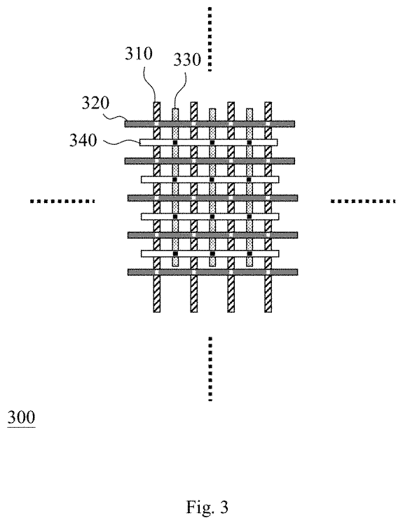

FIG. 3 shows another embodiment of the cross-type semiconductor capacitor array layout of the present disclosure. The cross-type semiconductor capacitor array layout 300 of FIG. 3 includes a first conductive structure and a second conductive structure. The first conductive structure includes longitudinal first conductive strips (i.e., the longitudinal strips 310 marked with slashes in FIG. 3) and lateral first conductive strips (i.e., the gray lateral strips 320 in FIG. 3). The second conductive structure includes longitudinal second conductive strips (i.e., the longitudinal strips 330 marked with dots in FIG. 3) and lateral second conductive strips (i.e., the white lateral strips 340 in FIG. 3). The longitudinal first conductive strips 310 and the longitudinal second conductive strips 330 are alternatively disposed in a first IC layer (e.g., a metal layer of the aforementioned multiple IC layer). Between two adjacent longitudinal first conductive strips 310 lies one longitudinal second conductive strip 330, and between two adjacent longitudinal second conductive strips 330 lies one longitudinal first conductive strip 310. The lateral first conductive strips 320 and the lateral second conductive strips 340 are alternatively disposed in a second IC layer (e.g., a metal layer above/below the first IC layer). Between two adjacent lateral first conductive strips 320 lies one lateral second conductive strip 340, and between two adjacent lateral second conductive strips 340 lies one lateral second conductive strip 320. The lateral first conductive strips 320 are coupled to the longitudinal first conductive strips 310 through first vias (i.e., the white blocks coupling the lateral first conductive strips 320 with the longitudinal first conductive strips 310 in FIG. 3). The lateral second conductive strips 340 are coupled to the longitudinal second conductive strips 330 through second vias (i.e., the black blocks coupling the lateral second conductive strips 340 with the longitudinal second conductive strips 330 in FIG. 3).

Since people having ordinary skill in the art can refer to the disclosure of the embodiment of FIG. 2 to appreciate the detail and modification of the embodiment of FIG. 3, repeated and redundant description is omitted here.

It should be noted that the size (i.e., the length, width, and thickness) of the strip-shaped conductor (e.g., a conductive strip or a voltage supply strip) mentioned in the present specification is not limited to specific specifications and can be determined according to the demand for implementation. It should also be noted that people of ordinary skill in the art can selectively use some or all of the features of any embodiment in this specification or selectively use some or all of the features of multiple embodiments in this specification to implement the present invention as long as such implementation is practicable; in other words, the present invention can be carried out flexibly in accordance with the present disclosure.

To sum up, the semiconductor capacitor array layout of the present disclosure can mitigate the problem of the prior art about parasitic capacitance and can prevent the problem caused by the U-shaped structure of the prior art applied in an advanced process.

The aforementioned descriptions represent merely the preferred embodiments of the present invention, without any intention to limit the scope of the present invention thereto. Various equivalent changes, alterations, or modifications based on the claims of the present invention are all consequently viewed as being embraced by the scope of the present invention.

What is claimed is:

1. A cross-type semiconductor capacitor array layout comprising:
a first conductive structure including longitudinal first conductive strips and lateral first conductive strips, wherein:
the longitudinal first conductive strips are located in a first integrated circuit (IC) layer, the longitudinal first conductive strips include a first longitudinal first-conductive-strip group and a second longitudinal first-conductive-strip group, the first longitudinal first-conductive-strip group is located in a first layout region of the first IC layer, the second longitudinal first-conductive-strip group is located in a second layout region of the first IC layer, the first layout region is adjacent to the second layout region, each group of the first longitudinal first-conductive-strip group and the second longitudinal first-conductive-strip group includes M longitudinal first conductive strips, the M longitudinal first conductive strips jointly define (M−1) gap(s), the first longitudinal first-conductive-strip group and the second longitudinal first-conductive-strip group as a whole include 2M longitudinal first conductive strips, and the M is an integer greater than one; and
the lateral first conductive strips are located in a second IC layer, the lateral first conductive strips include N lateral first conductive strips, a first part of the N lateral first conductive strips is located in a first vertical projection region of the first layout region, a second part of the N lateral first conductive strips is located in a second vertical projection region of the second layout region, both the first vertical projection region and the second vertical projection region are in the second IC layer, the N lateral first conductive strips jointly define (N−1) gap(s), the N lateral first conductive strips are coupled to the 2M longitudinal first conductive strips through first vias, and the N is an integer greater than one; and
a second conductive structure including longitudinal second conductive strips and lateral second conductive strips, wherein:
the longitudinal second conductive strips are located in the first IC layer, the longitudinal second conductive strips include a first longitudinal second-conductive-strip group and a second longitudinal second-conductive-strip group, each group of the first longitudinal second-conductive-strip group and the second longitudinal second-conductive-strip group includes (M−1) longitudinal second conductive strip(s), the (M−1) longitudinal second conductive strip(s) of the first longitudinal second-conductive-strip group is/are positioned in the (M−1) gap(s) defined by the first longitudinal first-conductive-strip group and is/are electrically insulated from the first longitudinal first-conductive-strip group, the (M−1) longitudinal second conductive strip(s) of the second longitudinal second-conductive-strip group is/are positioned in the (M−1) gap(s) defined by the second longitudinal first-conductive-strip group and is/are electrically insulated from the second longitudinal first-conductive-strip group; and
the lateral second conductive strips are located in the second IC layer, the lateral second conductive strips include a first lateral second-conductive-strip group and a second lateral second-conductive-strip group, each group of the first lateral second-conductive-strip group and the second lateral second-conductive-strip group includes (N−1) lateral second conductive strip(s) and is electrically insulated from the lateral first conductive strips, the (N−1) lateral second conductive strip(s) of the first lateral second-conductive-strip group is/are located in the first vertical projection region, positioned in the (N−1) gap(s) defined by the N lateral first conductive strips, and coupled to the (M−1) longitudinal second conductive strip(s) of the first longitudinal second-conductive-strip group through second vias, the (N−1) lateral second conductive strip(s) of the second lateral second-conductive-strip group is/are located in the second vertical projection region, positioned in the (N−1) gap(s) defined by the N lateral first conductive strips, and coupled to the (M−1) longitudinal second conductive strip(s) of the second longitudinal second-conductive-strip group through third vias.

2. The cross-type semiconductor capacitor array layout of claim 1, wherein a length of each of the N lateral first conductive strips is longer than a length of each of the (N−1) lateral second conductive strip(s).

3. The cross-type semiconductor capacitor array layout of claim 1, wherein a number of the first vias is not fewer than a number K, and the number K is the smaller one among N and 2M.

4. The cross-type semiconductor capacitor array layout of claim 1, wherein each of a number of the second vias and a number of the third vias is not fewer than a number K, the number K is the smaller one among (N−1) and (M−1), and the number K is not greater than [(M−1)×(N−1)].

5. The cross-type semiconductor capacitor array layout of claim 1, wherein the first IC layer and the second IC layer are a first metal layer and a second metal layer respectively, and no other metal layer is between the first metal layer and the second metal layer.

6. The cross-type semiconductor capacitor array layout of claim 1, wherein the longitudinal first conductive strips are parallel in a first direction, the lateral first conductive strips are parallel in a second direction, the longitudinal second conductive strips are parallel in the first direction, the lateral second conductive strips are parallel in the second direction, and the first direction is perpendicular to the second direction.

7. The cross-type semiconductor capacitor array layout of claim 1, wherein no lateral conductive strip is disposed in any of the first layout region and the second layout region, and no longitudinal conductive strip is disposed in any of the first vertical projection region and the second vertical projection region.

8. The cross-type semiconductor capacitor array layout of claim 1, wherein in the first layout region and the first vertical projection region, the first conductive structure and the second conductive structure jointly form a capacitor unit; and in the second layout region and the second vertical projection region, the first conductive structure and the second conductive structure jointly form another capacitor unit.

9. A cross-type semiconductor capacitor array layout comprising:
a first conductive structure including longitudinal first conductive strips and lateral first conductive strips; and
a second conductive structure including longitudinal second conductive strips and lateral second conductive strips;
wherein the longitudinal first conductive strips and the longitudinal second conductive strips are alternatively disposed in a first integrated circuit (IC) layer; the lateral first conductive strips and the lateral second conductive strips are alternatively disposed in a second IC layer; the lateral first conductive strips are coupled to the longitudinal first conductive strips through first vias; and the lateral second conductive strips are coupled to the longitudinal second conductive strips through second vias.

10. The cross-type semiconductor capacitor array layout of claim 9, wherein the first IC layer and the second IC layer are a first metal layer and a second metal layer respectively, and no other metal layer is between the first metal layer and the second metal layer.

11. The cross-type semiconductor capacitor array layout of claim 9, wherein the longitudinal first conductive strips are parallel in a first direction, the lateral first conductive strips are parallel in a second direction, the longitudinal second conductive strips are parallel in the first direction, the lateral second conductive strips are parallel in the second direction, and the first direction is perpendicular to the second direction.

12. The cross-type semiconductor capacitor array layout of claim 9, wherein the longitudinal first conductive strips and the longitudinal second conductive strips are located in a layout region of the first IC layer, and no lateral conductive strip is disposed in the layout region.

13. The cross-type semiconductor capacitor array layout of claim 12, wherein the lateral second conductive strips and at least a part of the lateral first conductive strips are in a vertical projection region of the layout region; the vertical projection region is in the second IC layer; and no longitudinal conductive strip is disposed in the vertical projection region.
